(19) United States
(12) Patent Application Publication
(10) Pub. No.: US 2024/0379635 A1
(43) Pub. Date: Nov. 14, 2024

(54) 3D INTEGRATED CIRCUIT (3DIC) STRUCTURE AND METHOD FOR MANUFACTURING THE SAME

(71) Applicant: SAMSUNG ELECTRONICS CO., LTD., Suwon-si (KR)

(72) Inventors: Choongbin YIM, Suwon-si (KR); Jongkook KIM, Suwon-si (KR); Chengtar WU, Suwon-si (KR)

(73) Assignee: SAMSUNG ELECTRONICS CO., LTD., Suwon-si (KR)

(21) Appl. No.: 18/601,335

(22) Filed: Mar. 11, 2024

(30) Foreign Application Priority Data
May 12, 2023 (KR) 10-2023-0061928

(51) Int. Cl. H01L 25/10; H01L 21/56; H01L 23/00; H01L 23/28; H01L 23/498; H01L 25/00

(52) U.S. Cl. CPC H01L 25/105; H01L 21/56; H01L 23/28; H01L 23/49827; H01L 24/08; H01L 24/19; H01L 24/20; H01L 24/80; H01L 25/50; H01L 2224/08145; H01L 2224/08225; H01L 2224/19; H01L 2224/21; H01L 2224/80895; H01L 2224/80896

(57) ABSTRACT

Provided a three-dimensional (3D) integrated circuit structure including a redistribution structure, a first semiconductor die on the redistribution structure, a substrate on the redistribution structure and adjacent to the first semiconductor die, a molding material on the redistribution structure and between the first semiconductor die and the substrate, an interconnection structure on the substrate and the first semiconductor die, the interconnection structure including a plurality of first bonding pads and a plurality of second bonding pads, and each second bonding pad of the second bonding pads being directly bonded to each first bonding pad of the first bonding pads, and a second semiconductor die on the interconnection structure.

### CROSS-REFERENCE TO RELATED APPLICATION

This application claims priority to Korean Patent Application No. 10-2023-0061928, filed in the Korean Intellectual Property Office on May 12, 2023, the disclosure of which is incorporated by reference herein in its entirety.

### BACKGROUND

### 1. Field

Embodiments of the present disclosure relate to a 3D integrated circuit (3DIC) structure and a manufacturing method for the same.

### 2. Description of Related Art

The semiconductor industry seeks to increase integration density so that more passive or active devices can be integrated within a given area. The development of technology for miniaturizing a circuit line width of a front-end semiconductor process has been gradually facing limitations, and accordingly, the semiconductor industry has been supplementing limitations of front-end semiconductor processes by developing semiconductor package techniques capable of having high integration densities. According to this trend, a three-dimensional (3D) integrated circuit (3DIC) capable of reducing a physical size of a semiconductor device has been developed.

The 3D integrated circuit (3DIC) a stacked semiconductor device that is manufactured by separately disposing a central processing unit (CPU), a graphic processing unit (GPU), a memory, a communication chip, a sensor, etc. on upper and lower wafers, and by bonding the upper wafer and the lower wafer by performing a suitable bonding process. The integrated circuit (3DIC) may offer greater density with a relatively smaller form factor, enabling increased performance and may reduce power consumption.

Among such 3D integrated circuits (3DIC), in a 3D integrated circuit (3DIC) having a stacked structure in which an area of a lower surface of an upper semiconductor die is greater than an area of an upper surface of a lower semiconductor die, the upper semiconductor die is electrically connected to the lower semiconductor die and a redistribution layer (RDL) structure, and in this case, the upper semiconductor die and the redistribution (RDL) structure are electrically connected by a metal (copper) post.

However, in the case of the metal post, in order to form a metal post with a relatively large height, a same process such as exposure, development, etching, and deposition must be repeatedly performed, and accordingly, a turnaround time (TAT) may increase and a risk of lowering yield may occur.

Therefore, it is necessary to develop a new 3D integrated circuit (3DIC) technology that can solve such problems of the conventional 3D integrated circuit (3DIC) technology.

### SUMMARY

According to an aspect of an embodiment, there is provided a three-dimensional (3D) integrated circuit structure including a redistribution structure, a first semiconductor die on the redistribution structure, a substrate on the redistribution structure and adjacent to the first semiconductor die, a molding material on the redistribution structure and between the first semiconductor die and the substrate, an interconnection structure on the substrate and the first semiconductor die, the interconnection structure including a plurality of first bonding pads and a plurality of second bonding pads, and each second bonding pad of the second bonding pads being directly bonded to each first bonding pad of the first bonding pads, and a second semiconductor die on the interconnection structure.

According to another aspect of an embodiment, there is provided a three-dimensional (3D) integrated circuit structure including a redistribution structure including a plurality of redistribution vias, a first semiconductor die on the redistribution structure, a substrate on the redistribution structure and adjacent to the first semiconductor die, a molding material on the redistribution structure and molding the first semiconductor die and the substrate, an interconnection structure on the substrate and the first semiconductor die, the interconnection structure including a plurality of first bonding pads, a plurality of second bonding pads, a first silicon insulating layer adjacent to side surfaces of the first bonding pads, and a second silicon insulating layer adjacent to side surfaces of the second bonding pads, each second bonding pad of the second bonding pads being directly bonded to each first bonding pad of the first bonding pads, and a second semiconductor die on the interconnection structure.

According to another aspect of an embodiment, there is provided a manufacturing method of a three-dimensional (3D) integrated circuit structure, including providing a lower surface of a first semiconductor die and a lower surface of a substrate onto a carrier, molding the first semiconductor die and the substrate on the carrier with a molding material, performing hybrid bonding to electrically connect the lower surface of the second semiconductor die to an upper surface of the first semiconductor die and an upper surface of the substrate, debonding the carrier from the lower surface of the first semiconductor die and the lower surface of the substrate, and forming a redistribution structure on the lower surface of the first semiconductor die and the lower surface of the substrate.

### BRIEF DESCRIPTION OF DRAWINGS

Embodiments will be more clearly understood from the following detailed description taken in conjunction with the accompanying drawings in which:

FIG. 1 illustrates a cross-sectional view showing a 3D integrated circuit (3DIC) structure according to an embodiment in which an upper second semiconductor die and a redistribution (RDL) structure are electrically connected by a substrate positioned next to a side surface of a lower first semiconductor die, and the substrate and the first semiconductor die are bonded to the second semiconductor die by hybrid bonding in n a 3D integrated circuit (3DIC) structure having a stacked structure in which an area of a lower surface of the second semiconductor die is greater than an area of an upper surface of the first semiconductor die;

FIG. 2 illustrates footprints of a lower first semiconductor die, a substrate positioned next to a first side surface of the first semiconductor die, a molding material, and an upper second semiconductor die in a 3D integrated circuit (3DIC) structure having a stacked structure in which an area of a lower surface of the second semiconductor die is greater than an area of an upper surface of the first semiconductor die;

FIG. 3 illustrates footprints of a lower first semiconductor die, a first substrate positioned next to a first side surface of the first semiconductor die, a second substrate positioned next to a second side surface of the first semiconductor die, a molding material, and an upper second semiconductor die in a 3D integrated circuit (3DIC) structure having a stacked structure in which an area of a lower surface of the second semiconductor die is greater than an area of an upper surface of the first semiconductor die;

FIG. 4 illustrates footprints of a lower first semiconductor die, a substrate surrounding two side surfaces of the first semiconductor die, a molding material, and an upper second semiconductor die in a 3D integrated circuit (3DIC) structure having a stacked structure in which an area of a lower surface of the second semiconductor die is greater than an area of an upper surface of the first semiconductor die;

FIG. 5 illustrates a cross-sectional view showing a 3D integrated circuit (3DIC) structure according to an embodiment in which at least one substrate are positioned next to a first side surface of a lower first semiconductor die and next to a second side surface opposite to the first side surface to electrically connect the second semiconductor die and a redistribution (RDL) structure, and the at least one substrate and the first semiconductor die are bonded to the second semiconductor die by hybrid bonding in a 3D integrated circuit (3DIC) structure having a stacked structure in which an area of a lower surface of the second semiconductor die is greater than an area of an upper surface of the first semiconductor die;

FIG. 6 illustrates footprints of a lower first semiconductor die, a first substrate positioned next to a first side surface of the first semiconductor die, a second substrate positioned next to a second side surface opposite to the first side surface, a molding material, and an upper second semiconductor die in a 3D integrated circuit (3DIC) structure having a stacked structure in which an area of a lower surface of the second semiconductor die is greater than an area of an upper surface of the first semiconductor die;

FIG. 7 illustrates footprints of a lower first semiconductor die, a first substrate, a second substrate, a third substrate, and a fourth substrate respectively positioned newt to various side surfaces of the first semiconductor die, a molding material, and an upper second semiconductor die in a 3D integrated circuit (3DIC) structure having a stacked structure in which an area of a lower surface of the second semiconductor die is greater than an area of an upper surface of the first semiconductor die;

FIG. 8 illustrates footprints of a lower first semiconductor die, a substrate surrounding four side surfaces of the first semiconductor die, a molding material, and an upper second semiconductor die in a 3D integrated circuit (3DIC) structure having a stacked structure in which an area of a lower surface of the second semiconductor die is greater than an area of an upper surface of the first semiconductor die;

FIG. 9 illustrates a cross-sectional view showing a step of mounting a first semiconductor die and a substrate on a first carrier as one of steps of a method of manufacturing a 3D integrated circuit (3DIC) structure according to a first embodiment;

FIG. 10 illustrates a cross-sectional view showing a step of molding a first semiconductor die and a substrate with a molding material on a first carrier as one of steps of a method of manufacturing a 3D integrated circuit (3DIC) structure according to the first embodiment;

FIG. 11 illustrates a cross-sectional view showing a step of debonding a first carrier from a lower surface of a first semiconductor die and a lower surface of a substrate as one of steps of a method of manufacturing a 3D integrated circuit (3DIC) structure according to the first embodiment;

FIG. 12 illustrates a cross-sectional view showing a step of forming a redistribution (RDL) structure on a lower surface of a first semiconductor die and a lower surface of a substrate as one of steps of a method of manufacturing a 3D integrated circuit (3DIC) structure according to the first embodiment;

FIG. 13 illustrates a cross-sectional view showing a step of flattening a molding material as one of steps of a method of manufacturing a 3D integrated circuit (3DIC) structure according to the first embodiment;

FIG. 14 illustrates a cross-sectional view showing a step of bonding a second semiconductor die on an upper surface of a first semiconductor die and an upper surface of a substrate by performing hybrid bonding as one of steps of a method of manufacturing a 3D integrated circuit (3DIC) structure according to the first embodiment;

FIG. 15 illustrates a cross-sectional view showing a step of mounting a first semiconductor die and a substrate on a second carrier as one of steps of a method of manufacturing a 3D integrated circuit (3DIC) structure according to a second embodiment;

FIG. 16 illustrates a cross-sectional view showing a step of molding a first semiconductor die and a substrate on a second carrier as one of steps of a method of manufacturing a 3D integrated circuit (3DIC) structure according to the second embodiment;

FIG. 17 illustrates a cross-sectional view showing a step of flattening a molding material as one of steps of a method of manufacturing a 3D integrated circuit (3DIC) structure according to the second embodiment;

FIG. 18 illustrates a cross-sectional view showing a step of bonding a second semiconductor die on an upper surface of a first semiconductor die and an upper surface of a substrate by performing hybrid bonding as one of steps of a method of manufacturing a 3D integrated circuit (3DIC) structure according to the second embodiment;

FIG. 19 illustrates a cross-sectional view showing a step of debonding a second carrier from a lower surface of a first semiconductor die and a lower surface of a substrate as one of steps of a method of manufacturing a 3D integrated circuit (3DIC) structure according to the second embodiment; and

FIG. 20 illustrates a cross-sectional view showing a step of forming a redistribution (RDL) structure on a lower surface of a first semiconductor die and a lower surface of a substrate as one of steps of a method of manufacturing a 3D integrated circuit (3DIC) structure according to the second embodiment.

### DETAILED DESCRIPTION

The present disclosure will be described more fully hereinafter with reference to the accompanying drawings, in which embodiments of the present disclosure are shown. As those skilled in the art would realize, the described embodiments may be modified in various different ways, all without departing from the spirit or scope of the present invention. Embodiments described herein are example embodiments, and thus, the disclosure is not limited thereto.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present invention is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

Hereinafter, a 3D integrated circuit structure 100 and a manufacturing method for the 3D integrated circuit structure 100 according to an embodiment will be described with reference to the drawings.

The 3D integrated circuit (3DIC) structure 100 implements an integrated circuit as a three-dimensional chip, and refers to a technique in which a circuit stacking method is converted from a conventional horizontal method to a vertical method. Using the vertical stacking method, more devices may be implemented on a same area of a silicon wafer, reducing manufacturing cost and improving performance.

The 3D integrated circuit (3DIC) structure 100 may have a stacked structure in which a lower semiconductor die is greater than an upper semiconductor die, or a stacked structure in which the upper semiconductor die is greater than the lower semiconductor die. In the stack structure in which the lower semiconductor die is greater than the upper semiconductor die, an entire lower surface of the upper semiconductor die is bonded to the lower semiconductor die by a connection member (e.g., a micro bump) positioned under the upper semiconductor die. In the stack structure in which the upper semiconductor die is greater than the lower semiconductor die, an interconnection member is additionally required for a portion of the lower surface of the upper semiconductor die that is not bonded to an upper surface of the lower semiconductor die.

A technique of forming a metal (copper) post as the interconnection member is known in related art. However, with the development of technology, a high aspect ratio metal post is required, and in order to form the high aspect ratio metal post, a same processes such as exposure, development, etching, and deposition must be repeatedly performed. Therefore, according to a process of forming a metal post with a high aspect ratio, a turnaround time (TAT) increases and a risk of lowering yield may occur.

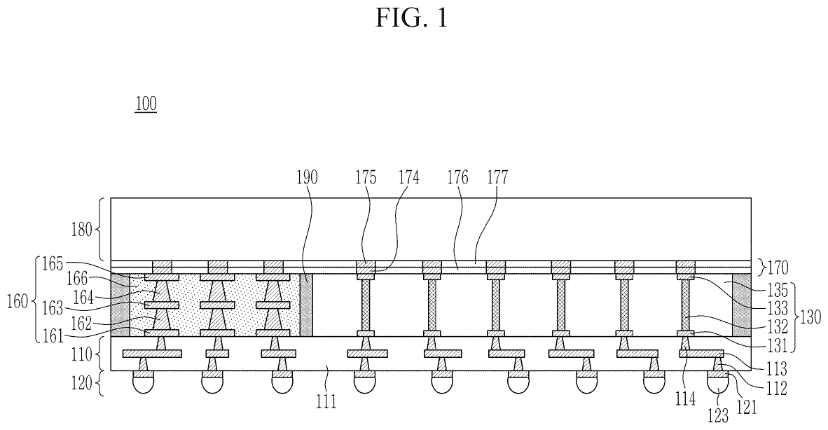

FIG. 1 illustrates a cross-sectional view showing a 3D integrated circuit (3DIC) structure according to an embodiment Referring to FIG. 1, the 3D integrated circuit (3DIC) structure 100 may include the redistribution (RDL) structure 110, an external connection structure 120, the first semiconductor die 130, the substrate 160, an Interconnection structure 170, the second semiconductor die 180, and a molding material 190. In an embodiment, the 3D integrated circuit (3DIC) structure 100 may be a system on chip (SOC).

Referring to FIG. 1, the upper second semiconductor die 180 and the redistribution (RDL) structure 110 may be electrically connected to each other through a substrate 160 positioned adjacent to a side surface of a lower first semiconductor die 130. For example, the substrate 160 and the lower first semiconductor die 130 may be arranged side-by-side to be laterally connected to each other with the molding material 190 therebetween. The substrate 160 and the first semiconductor die 130 may be bonded to the second semiconductor die 180 by hybrid bonding in a 3D integrated circuit (3DIC) structure 100 having a stacked structure in which an area of a lower surface of the second semiconductor die 180 is greater than an area of an upper surface of the first semiconductor die 130.

The redistribution (RDL) structure 110 may include a dielectric layer 111 and first redistribution vias 112, first redistribution lines 113, and second redistribution vias 114 within the dielectric layer 111. However, embodiments are not limited thereto. For example, redistribution (RDL) structures 110 may include fewer or greater numbers of redistribution lines and redistribution vias.

The first redistribution via 112 may be positioned between the first redistribution line 113 and a conductive pad 121. The first redistribution via 112 may electrically connect the first redistribution line 113 to an external connection member 123 connected to the conductive pad 121 in a vertical direction. The first redistribution line 113 may be positioned between the first redistribution via 112 and the second redistribution via 114. The first redistribution line 113 may electrically connect the first redistribution via 112 and the second redistribution via 114 in a horizontal direction. The second redistribution via 114 may be positioned between the first redistribution line 113 and a first wiring layer 161 of the substrate 160, and between the first redistribution line 113 and a first connection pad 131 of the first semiconductor die 130. The second redistribution via 114 may electrically connect the first wiring layer 161 of the substrate 160 to the first redistribution line 113 and the first connection pad 131 of the first semiconductor die 130 to the first redistribution line 113 in the vertical direction.

The external connection structure 120 may be positioned on a lower surface of the redistribution (RDL) structure 110. The external connection structure 120 may include conductive pads 121 and external connection members 123. The conductive pad 121 may electrically connect the first redistribution via 112 of the redistribution structure 110 to the external connection member 123. The external connection member 123 may electrically connect the 3D integrated circuit (3DIC) structure 100 to an external device. In an embodiment, the external connection member 123 may include a solder ball or bump.

The first semiconductor die 130 may be positioned on the redistribution (RDL) structure 110. The first semiconductor die 130 may include first connection pads 131, through silicon vias (TSVs) 132, second connection pads 133, and first semiconductor chips 135.

The first connection pad 131 may be positioned between the through silicon via (TSV) 132 and the second redistribution via 114. The first connection pad 131 may electrically connect the through silicon via (TSV) 132 to the second redistribution via 114. The first connection pad 131 may be directly bonded to the second redistribution via 114.

The through silicon via (TSV) 132 may be positioned between the first connection pad 131 and the second connection pad 133. The through silicon via (TSV) 132 may electrically connect the second connection pad 133 to the first connection pad 131. A first end of the through silicon via (TSV) 132 may contact the first connection pad 131, and a second end of the through silicon via (TSV) 132 may contact the second connection pad 133.

The second connection pad 133 may be positioned between the through silicon via (TSV) 132 and a first bonding pad 174 of the interconnection structure 170. The second connection pad 133 may electrically connect the first bonding pad 174 of the interconnection structure 170 to the through silicon via (TSV) 132. The second connection pad 133 may be directly bonded to the first bonding pad 174 of the interconnection structure 170.

In an embodiment, the through silicon via (TSV) 132 may include, for example at least one of tungsten, aluminum, copper, or an alloy thereof. Each of the first connection pad 131 and the second connection pad 133 may include, for example, at least one of copper, aluminum, silver, tin, gold, nickel, lead, titanium, or an alloy thereof.

A first semiconductor chip 135 may include at least one of a central processing unit (CPU) or a graphic processing unit (GPU).

In the 3D integrated circuit (3DIC) structure 100, the second semiconductor die 180 is positioned to be spaced apart from the redistribution (RDL) structure 110 that may transfer signals and power, and thus a speed of receiving and responding to signals and power of the second semiconductor die 180 may be increased by positioning the through silicon via (TSV) 132 in the first semiconductor die 130 and connecting the TSV to the second semiconductor die 180.

The substrate 160 may be positioned on the redistribution (RDL) structure 110 and adjacent to the first semiconductor die 130. For example, the substrate 160 and the lower first semiconductor die 130 may be arranged side-by-side to be laterally connected to each other with the molding material 190 therebetween. The substrate 160 may include a first wiring layer 161, a first via 162, a second wiring layer 163, a second via 164, a third wiring layer 165, and an insulating layer 166. The substrate 160 may be positioned between the redistribution (RDL) structure 110 and the second semiconductor die 180 connected to the interconnection structure 170. The substrate 160 may electrically connect the second semiconductor die 180 connected to the interconnection structure 170 to the redistribution (RDL) structure 110. The substrate 160 may include a printed circuit board (PCB). The substrate 160 may include an embedded trace substrate (ETS).

According to embodiments, the substrate 160 may be used to electrically connect the second semiconductor die 180 to the redistribution (RDL) structure 110 instead of using a metal (copper) post to electrically connect the second semiconductor die 180 to the redistribution (RDL) structure 110, in the 3D integrated circuit (3DIC) structure 100 having a stacked structure in which an area of a lower surface of the second semiconductor die 180 is greater than an area of an upper surface of the first semiconductor die 130. As a result, it is possible to provide a 3D integrated circuit (3DIC) structure 100 having improved rigidity and being resistant to warpage. In addition, since the 3D integrated circuit (3DIC) structure 100 is manufactured using a substrate manufactured in advance, a process of manufacturing the 3D integrated circuit (3DIC) structure 100 may be more simplified, and a turnaround time (TAT) consumed in manufacturing the 3D integrated circuit (3DIC) structure 100 may be reduced. In addition, since the 3D integrated circuit (3DIC) structure 100 is manufactured using a substrate separately tested in advance, a product yield of the 3D integrated circuit (3DIC) structure 100 may be improved.

The first wiring layer 161 is disposed between the second redistribution via 114 and the first via 162 of the redistribution (RDL) structure 110. The first wiring layer 161 may electrically connect the first via 162 to the second redistribution via 114 of the redistribution structure 110. The first wiring layer 161 may be directly bonded to the second redistribution via 114. The first via 162 is positioned between the first wiring layer 161 and the second wiring layer 163. The first via 162 may electrically connect the second wiring layer 163 to the first wiring layer 161. The second wiring layer 163 is disposed between the first via 162 and the second via 164. The second wiring layer 163 may electrically connect the second via 164 to the first via 162. The second via 164 is positioned between the second wiring layer 163 and the third wiring layer 165. The second via 164 may electrically connect the third wiring layer 165 to the second wiring layer 163. The third wiring layer 165 is disposed between the second via 164 and the first bonding pad 174 of the interconnect structure 170. The third wiring layer 165 may electrically connect the first bonding pad 174 of the interconnect structure 170 to the second via 164. The insulating layer 166 may be provided adjacent to and surround the first wiring layer 161, the first via 162, the second wiring layer 163, the second via 164, and the third wiring layer 165. However, embodiments are not limited thereto. For example, the substrate 160 may include fewer or greater numbers of wiring layers, and vias.

In an embodiment, the first via 162 and the second via 164 may have a truncated cone shape in which a diameter of the first via 162 and the second via 164 become narrower from a lower surface to an upper surface. In an embodiment, the first via 162 and the second via 164 may have a truncated cone shape in which a diameter becomes narrower from an upper surface to a lower surface. However, embodiments are not limited thereto. For example, the first via 162 and the second via 164 may include a cylindrical shape having a constant diameter from an upper surface to a lower surface.

The interconnection structure 170 may include first bonding pads 174, second bonding pads 175, first silicon insulating layer 176, and second silicon insulating layer 177. The first bonding pads 174, the second bonding pads 175, the first silicon insulating layer 176, and the second silicon insulating layer 177 may be positioned between an upper surface of the substrate 160 and a lower surface of the second semiconductor die 180, and between an upper surface of the first semiconductor die 130 and a lower surface of the second semiconductor die 180. The first bonding pads 174 and the second bonding pads 175 may electrically connect the second semiconductor die 180 to the substrate 160 and the second semiconductor die 180 to the first semiconductor die 130.

In the 3D integrated circuit (3DIC) structure 100 according to embodiments, the first semiconductor die 130 and the second semiconductor die 180 and the substrate 160 and the second semiconductor die 180 may be bonded by hybrid bonding. The hybrid bonding is to bond two devices by fusing same materials of the two devices using a bonding property of a same material. Herein, hybrid indicates that two different types of bonding are made, e.g., bonding two devices with a first type of metal-metal bonding and a second type of non-metal-non-metal bonding. The hybrid bonding may make it possible to form I/Os with a relatively fine pitch.

The first bonding pads 174 may be directly bonded to the second bonding pads 175 by metal-metal hybrid bonding, and the first silicon insulation layer 176 may be directly bonded to the second silicon insulation layer 177 by non-metal-non-metal hybrid bonding.

The area of the lower surface of the second semiconductor die 180 may be greater than the area of the upper surface of the first semiconductor die 130. The second semiconductor die 180 may include second semiconductor chips. In an embodiment, the second semiconductor chip may include at least one of a sensor or a communication chip.

The molding material 190 may be positioned on the redistribution (RDL) structure, and may mold the first semiconductor die 130 and the substrate 160.

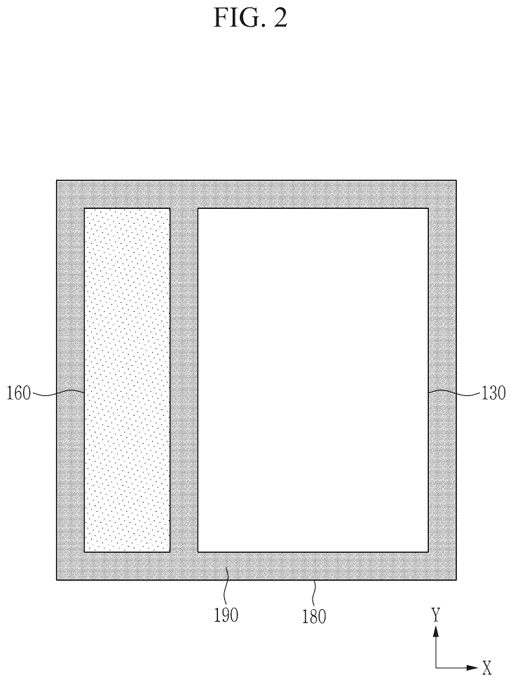

FIG. 2 illustrates a plan view of the 3D integrated circuit (3DIC) structure 100. FIG. 2 illustrates footprints of the lower first semiconductor die 130, the substrate 160 positioned adjacent to a first side surface of the first semiconductor die 130, the molding material 190, and the upper second semiconductor die 180. For example, the substrate 160 and the lower first semiconductor die 130 may be arranged side-by-side to be laterally connected to each other with the molding material 190 therebetween. In the 3D integrated circuit (3DIC) structure 100 having a stacked structure. As illustrated in FIG. 2, an area of a lower surface of the second semiconductor die 180 is greater than an area of an upper surface of the first semiconductor die 130.

Referring to FIG. 2, in order to additionally cover a footprint area of the second semiconductor die 180 that cannot be covered only by the first semiconductor die 130, the substrate 160 may be positioned next to a first side surface of first semiconductor die 130. The substrate 160 may cover the footprint area of the second semiconductor die 180 in the X direction that cannot be covered only by the first semiconductor die 130, and may have a function of electrically connecting the second semiconductor die 180 to the redistribution (RDL) structure 110 and structurally supporting the second semiconductor die 180.

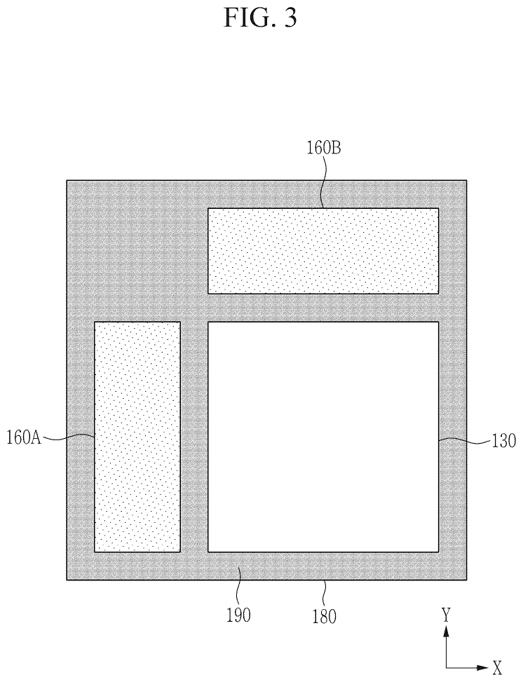

FIG. 3 illustrates a plan view of the 3D integrated circuit (3DIC) structure 100. FIG. 3 illustrates footprints of the lower first semiconductor die 130, a first substrate 160A positioned next to a first side surface of the first semiconductor die 130, a second substrate 160B positioned adjacent to a second side surface of the first semiconductor die 130, the molding material 190, and the upper second semiconductor die 180 in the 3D integrated circuit (3DIC) structure 100 having a stacked structure. For example, the first substrate 160A and the second substrate 160B and the first semiconductor die 130 may be arranged side-by-side to be laterally connected to each other with the molding material 190 therebetween. As illustrated in FIG. 3, an area of a lower surface of the second semiconductor die 180 is greater than an area of an upper surface of the first semiconductor die 130.

Referring to FIG. 3, the first semiconductor die 130 may be positioned such that the footprint area of the first semiconductor die 130 is positioned at one corner of the footprint area of the second semiconductor die 180. In order to additionally cover the footprint area of the second semiconductor die 180 that is not covered by the first semiconductor die 130, the first substrate 160A may be positioned at a left side of the first semiconductor die 130 in the X direction, and the second substrate 160B may be positioned above the first semiconductor die 130 in the Y direction. The first substrate 160A and the second substrate 160B may cover the footprint area of the second semiconductor die 180 that cannot be covered only by the first semiconductor die 130, and may have a function of electrically connecting the second semiconductor die 180 to the redistribution (RDL) structure 110 and structurally supporting the second semiconductor die 180.

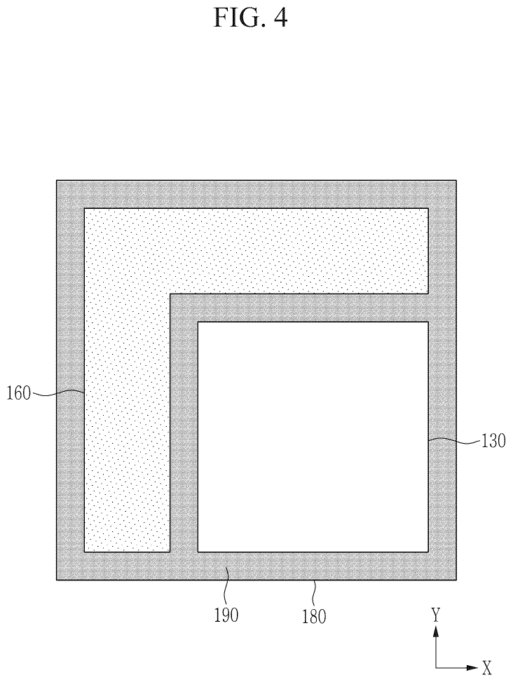

FIG. 4 illustrates a plan view of the 3D integrated circuit (3DIC) structure 100. FIG. 4 illustrates footprints of the lower first semiconductor die 130, the substrate 160 adjacent to two side surfaces of the first semiconductor die 130, the molding material 190, and the upper second semiconductor die 180 in the 3D integrated circuit (3DIC) structure 100 having a stacked structure. For example, the substrate 160 and the lower first semiconductor die 130 may be arranged side-by-side to be laterally connected to each other with the molding material 190 therebetween. As illustrated in FIG. 4, an area of a lower surface of the second semiconductor die 180 is greater than an area of an upper surface of the first semiconductor die 130.

Referring to FIG. 4, the first semiconductor die 130 may be positioned such that the footprint area of the first semiconductor die 130 is positioned at one corner of the footprint area of the second semiconductor die 180. In order to additionally cover the footprint area of the second semiconductor die 180 that is not covered by the first semiconductor die 130, the substrate 160 surrounding a left side of the first semiconductor die 130 in the X direction and an upper side of the first semiconductor die 130 in the Y direction may be positioned. The substrate 160 may cover the footprint area of the second semiconductor die 180 that cannot be covered only by the first semiconductor die 130, and may have a function of electrically connecting the second semiconductor die 180 to the redistribution (RDL) structure 110 and structurally supporting the second semiconductor die 180.

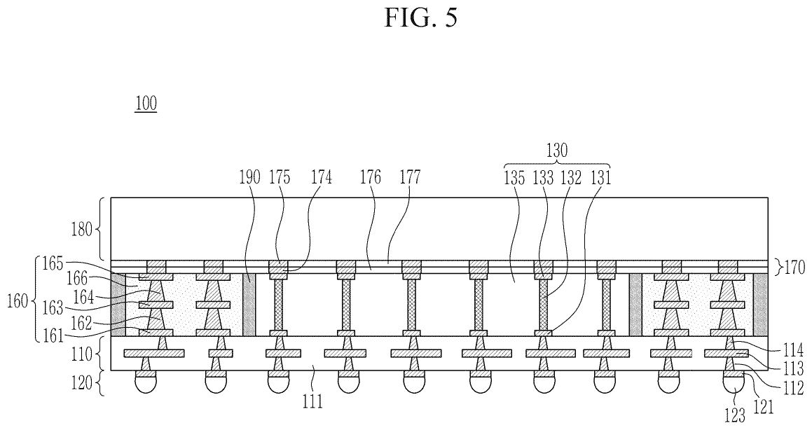

FIG. 5 illustrates a cross-sectional view showing the 3D integrated circuit (3DIC) structure 100 according to an embodiment in which at least one substrate 160 is positioned adjacent to a first side surface of the lower first semiconductor die 130 and adjacent to a second side surface opposite to the first side surface to electrically connect the second semiconductor die 180 and the redistribution (RDL) structure 110. For example, the substrate 160 may be arranged side-by-side to be laterally connected to the first side surface and the second side surface of the lower first semiconductor die 130 with the molding material 190 therebetween. The at least one substrate 160 and the first semiconductor die 130 are bonded to the second semiconductor die 180 by hybrid bonding in the 3D integrated circuit (3DIC) structure 100 having a stacked structure in which an area of a lower surface of the second semiconductor die 180 is greater than an area of an upper surface of the first semiconductor die 130.

Referring to FIG. 5, the substrate 160 may be positioned adjacent to a first side surface of the first semiconductor die 130 and a second side surface opposite to the first side surface. Since the area of the lower surface of the upper second semiconductor die 180 is greater than the area of the upper surface of the lower first semiconductor die 130, various arrangements of the substrate 160 and the first semiconductor die 130 on the redistribution (RDL) structure may be considered according to a type, arrangement, and connection relationship of the semiconductor chips included in the first semiconductor die 130 and the second semiconductor die 180. Thus, the substrate 160 may be positioned adjacent to several side surfaces of the first semiconductor die 130, the footprint of the first semiconductor die 130 and the footprint of the substrate 160 are included within the footprint of the second semiconductor die 180.

Except that the substrate 160 is positioned adjacent to the first side surface of the first semiconductor die 130 and the second side surface opposite to the first side surface in FIG. 5, other features and configurations are the same as those of FIG. 1. Accordingly, the contents described in FIG. 1 may be equally applied to other features and configurations other than that the substrate 160 is positioned adjacent to the first side surface of the first semiconductor die 130 and the second side surface opposite to the first side surface.

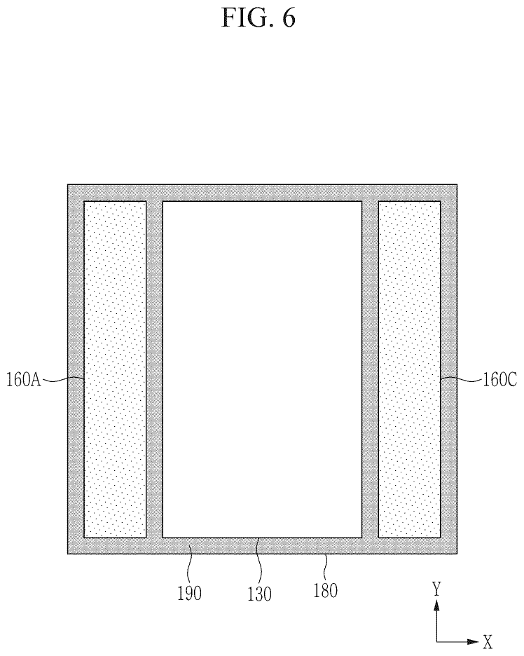

FIG. 6 a plan view of the 3D integrated circuit (3DIC) structure 100.

FIG. 6 illustrates footprints of the lower first semiconductor die 130, a first substrate 160A positioned adjacent to a first side surface of the first semiconductor die 130, a second substrate 160C positioned adjacent to a second side surface opposite to the first side surface, the molding material 190, and the upper second semiconductor die 180 in the 3D integrated circuit (3DIC) structure 100 having a stacked structure in which an area of a lower surface of the second semiconductor die 180 is greater than an area of an upper surface of the first semiconductor die 130. For example, the first substrate 160A and the second substrate 160B may be arranged side-by-side to be laterally connected to the first side surface and the second side surface of the lower first semiconductor die 130 with the molding material 190 therebetween.

Referring to FIG. 6, the first semiconductor die 130 may be positioned such that the footprint area of the first semiconductor die 130 is positioned at a center of the footprint area of the second semiconductor die 180 in the X direction. In order to additionally cover the footprint area of the second semiconductor die 180 that is not covered by the first semiconductor die 130, the first substrate 160A may be positioned adjacent to a first side surface of the first semiconductor die 130 in the X direction, and the second substrate 160C may be positioned adjacent to a second side surface opposite to the first side surface of the first semiconductor die 130. The substrate 160 may cover the footprint area of the second semiconductor die 180 that cannot be covered only by the first semiconductor die 130, and may have a function of electrically connecting the second semiconductor die 180 to the redistribution (RDL) structure 110 and structurally supporting the second semiconductor die 180.

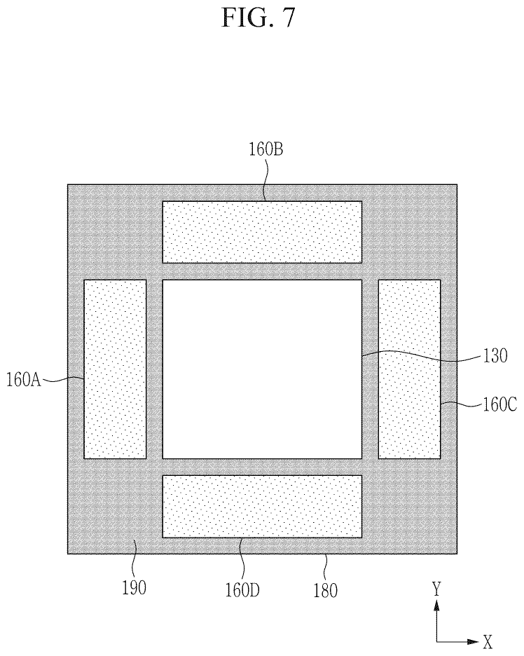

FIG. 7 a plan view of the 3D integrated circuit (3DIC) structure 100. FIG. 7 illustrates footprints of the lower first semiconductor die 130, a first substrate 160A, a second substrate 160B, a third substrate 160C, and a fourth substrate 160D respectively positioned on various side surfaces of the first semiconductor die 130, the molding material 190, and the upper second semiconductor die 130 in the 3D integrated circuit (3DIC) structure 100 having a stacked structure in which an area of a lower surface of the second semiconductor die 180 is greater than an area of an upper surface of the first semiconductor die 130.

Referring to FIG. 7, the first semiconductor die 130 may be positioned such that the footprint area of the first semiconductor die 130 is positioned in a center of the footprint area of the second semiconductor die 180 in the X direction and in the Y direction. In order to additionally cover the footprint area of the second semiconductor die 180 that is not covered by the first semiconductor die 130, the first substrate 160A, the second substrate 160B, the third substrate 160C, and the fourth substrate 160D may be positioned adjacent to various side surfaces of the first semiconductor die 130. For example, the first substrate 160A, the second substrate 160B, the third substrate 160C, and the fourth substrate 160D may be arranged side-by-side to be laterally connected to various side surfaces of the lower first semiconductor die 130 with the molding material 190 therebetween. The first substrate 160A, the second substrate 160B, the third substrate 160C, and the fourth substrate 160D may cover the footprint area of the second semiconductor die 180 that cannot be covered only by the first semiconductor die 130, and may have a function of electrically connecting the second semiconductor die 180 to the redistribution (RDL) structure 110 and structurally supporting the second semiconductor die 180.

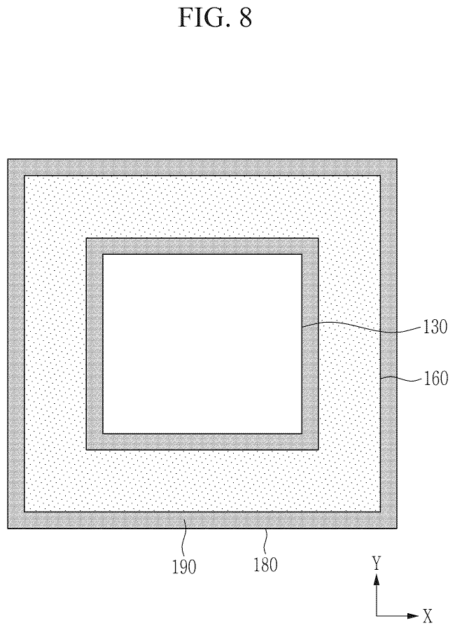

FIG. 8 a plan view of the 3D integrated circuit (3DIC) structure 100. FIG. 8 illustrates footprints of the lower first semiconductor die 130, the substrate 160 surrounding four side surfaces of the first semiconductor die 130, the molding material 190, and the upper second semiconductor die 180 in the 3D integrated circuit (3DIC) structure 100 having a stacked structure in which an area of a lower surface of the second semiconductor die 180 is greater than an area of an upper surface of the first semiconductor die 130.

Referring to FIG. 8, the first semiconductor die 130 may be positioned such that the footprint area of the first semiconductor die 130 is positioned in a center of the footprint area of the second semiconductor die 180 in the X direction and in the Y direction. In order to additionally cover the footprint area of the second semiconductor die 180 that is not covered by the first semiconductor die 130, the substrate 160 may be positioned adjacent to and to surround the four side surfaces of the first semiconductor die 130. For example, the substrate 160 may be arranged side-by-side to be laterally connected to the four side surfaces of the lower first semiconductor die 130 with the molding material 190. The substrate 160 may cover the footprint area of the second semiconductor die 180 that cannot be covered by the first semiconductor die 130, and may have a function of electrically connecting the second semiconductor die 180 to the redistribution (RDL) structure 110 and structurally supporting the second semiconductor die 180.

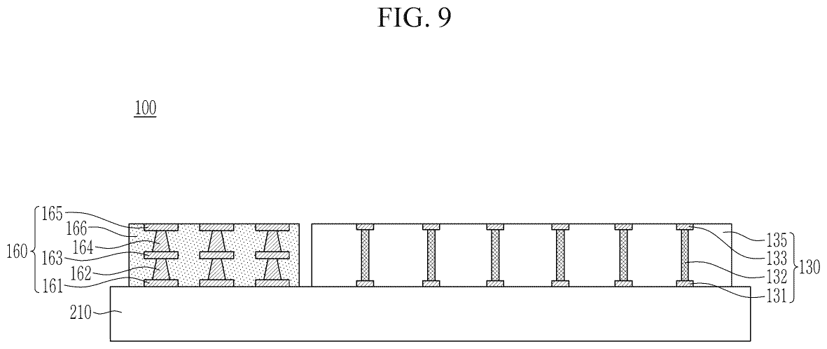

FIG. 9 illustrates a cross-sectional view showing a step of mounting the first semiconductor die 130 and the substrate 160 on a first carrier 210 as one of steps of a method of manufacturing the 3D integrated circuit (3DIC) structure 100 according to an embodiment.

Referring to FIG. 9, the first carrier 210 is provided. The first carrier 210 may include, e.g., a silicon-based material such as glass or a silicon oxide, an organic material, or another material such as an aluminum oxide, any combination of these materials, and the like.

The first semiconductor die 130 and the substrate 160 are mounted on the first carrier 210. The first semiconductor die 130 and the substrate 160 are horizontally arranged adjacent to each other and at a same level in a vertical direction. The first semiconductor die 130 is positioned with an active surface facing the first carrier 210. In an embodiment, the first semiconductor die 130 and the substrate 160 may be attached on the first carrier 210 by a laser. In an embodiment, an upper surface of the first semiconductor die 130 may be coplanar with an upper surface of the substrate 160. In an embodiment, a lower surface of the first semiconductor die 130 may be coplanar with a lower surface of the substrate 160.

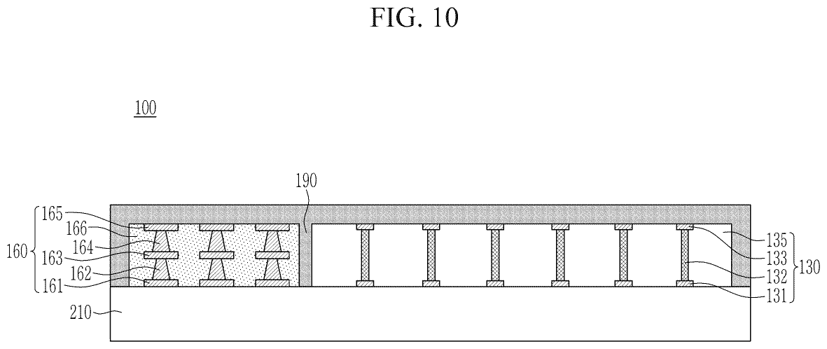

FIG. 10 illustrates a cross-sectional view showing a step of molding the first semiconductor die 130 and the substrate 160 with the molding material 190 on the first carrier 210 as one of the steps of the method of manufacturing the 3D integrated circuit (3DIC) structure according to the embodiment.

Referring to FIG. 10, the first semiconductor die 130 and the substrate 160 are molded with the molding material 190 on the first carrier 210. In an embodiment, the molding process with the molding material 190 may include a compression molding or transfer molding process. In an embodiment, the molding material 190 may include an epoxy molding compound (EMC).

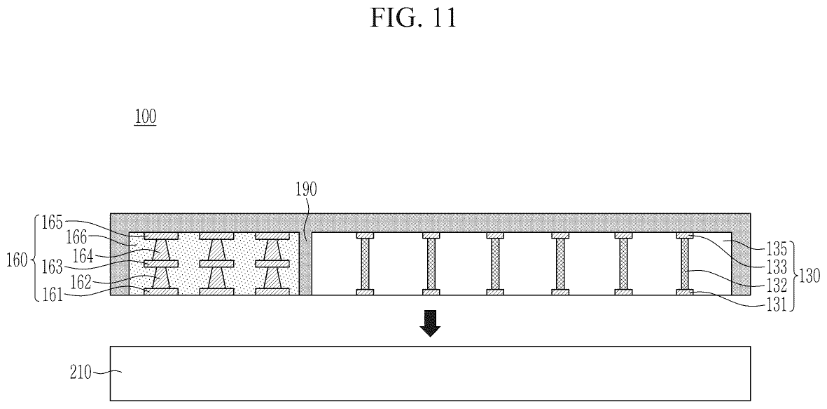

FIG. 11 illustrates a cross-sectional view showing a step of debonding the first carrier 210 from a lower surface of the first semiconductor die 130 and a lower surface of the substrate 160 as one of the steps of the method of manufacturing the 3D integrated circuit (3DIC) structure 100 according to the first embodiment.

Referring to FIG. 11, the first carrier 210 is debonded from the lower surface of the first semiconductor die 130 and the lower surface of the substrate 160.

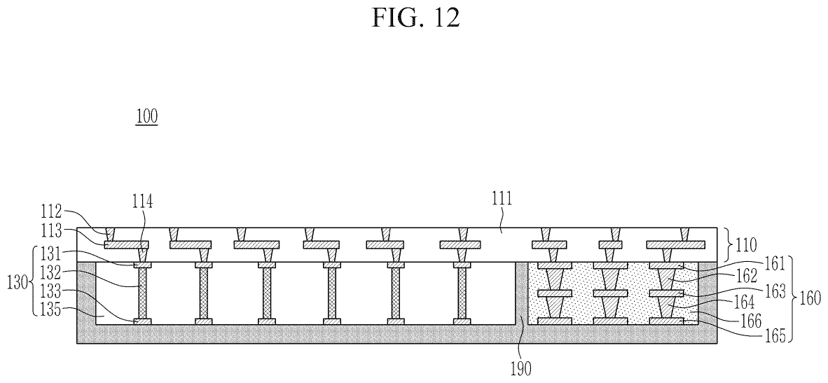

FIG. 12 illustrates a cross-sectional view showing a step of forming the redistribution (RDL) structure 100 on a lower surface of the first semiconductor die 130 and a lower surface of the substrate 160 as one of the steps of the method of manufacturing the 3D integrated circuit (3DIC) structure 100 according to the embodiment.

A dielectric layer 111 is formed on a lower surface of the molding material 190, a lower surface of the first semiconductor die 130, and a lower surface of the substrate 160. As the dielectric layer 111 is formed directly on the lower surface of the molding material 190, the lower surface of the first semiconductor die 130, and the lower surface of the substrate 160, the 3D integrated circuit (3DIC) structure 100 according to embodiments does not include connection members such as micro bumps and solder balls. In an embodiment, the dielectric layer 111 may include a photosensitive polymer layer. The photosensitive polymer is a material that may form fine patterns by applying a photolithography process. In an embodiment, the dielectric layer 111 may include a photosensitive insulator (photoimageable dielectric (PID)) used in a redistribution process. As an embodiment, the photoimageable insulator (PID) may include a polyimide-based photosensitive polymer, a novolak-based photosensitive polymer, polybenzoxazole, a silicone-based polymer, an acrylate-based polymer, or an epoxy-based polymer. In another embodiment, the dielectric layer 111 is formed of a polymer such as PBO and polyimide. In another embodiment, the dielectric layer 111 is formed of an inorganic dielectric material such as a silicon nitride, a silicon oxide, or the like. In an embodiment, the dielectric layer 111 may be formed by a CVD, ALD, or PECVD process.

After forming the dielectric layer 111, via holes are formed by selectively etching the dielectric layer 111, and the second redistribution vias 114 are formed by filling the via holes with a conductive material. A width of an uppermost portion of each second redistribution via among the second redistribution vias 114 is greater than a width of a lowermost portion. In a subsequent process, since a final product is manufactured by inverting the first semiconductor die 130 on which the redistribution (RDL) structure 110 is formed, in the final product, the width of the uppermost portion of each second redistribution via among the second redistribution vias 114 is smaller than the width of the lowermost portion of each second redistribution via among the second redistribution vias 114.

The dielectric layer 111 is additionally deposited on the second redistribution vias 114 and the dielectric layer 111, the additionally deposited dielectric layer 111 is selectively etched to form openings, and the first redistribution lines 113 are formed by filling the openings with a conductive material.

The dielectric layer 111 is additionally deposited on the first redistribution lines 113 and the dielectric layer 111, the additionally deposited dielectric layer 111 is selectively etched to form via holes, and the first redistribution vias 112 are formed by filling the via holes with a conductive material. Similar to the second redistribution vias 114, in the final product, a width of an uppermost portion of each first redistribution via among the first redistribution vias 112 is smaller than a width of a lowermost portion of each first redistribution via among the first redistribution vias 112.

In an embodiment, the first redistribution vias 112, the first redistribution lines 113, and the second redistribution vias 114 may include at least one of, for example, copper, aluminum, tungsten, nickel, gold, tin, titanium, or an alloy thereof. In an embodiment, the first redistribution vias 112, the first redistribution lines 113, and the second redistribution vias 114 may be formed by performing a sputtering process. In another embodiment, the first redistribution vias 112, the first redistribution lines 113, and the second redistribution vias 114 may be formed by performing an electroplating process after forming a seed metal layer.

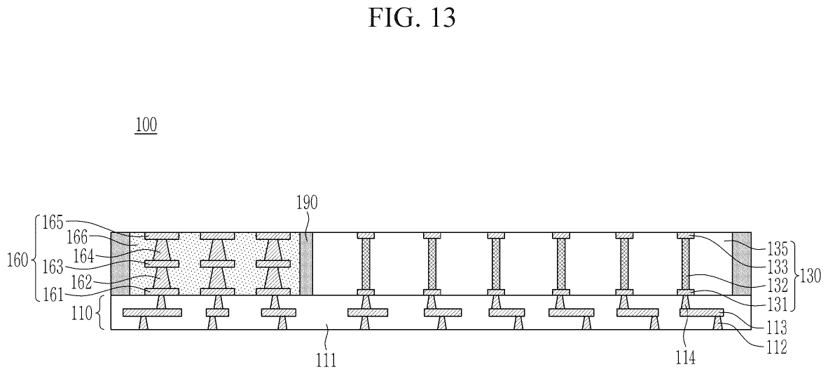

FIG. 13 illustrates a cross-sectional view showing a step of flattening the molding material 190 as one of the steps of the method of manufacturing the 3D integrated circuit (3DIC) structure 100 according to the embodiment.

Referring to FIG. 13, chemical mechanical polishing (CMP) is performed to level an upper surface of the molding material 190. The upper surface of the molding material 190 is planarized by applying a CMP process. After performing the CMP process, the first connection pads 133 are exposed on an upper surface of the first semiconductor die 130 and the third wiring layer 165 is exposed on an upper surface of the substrate 160.

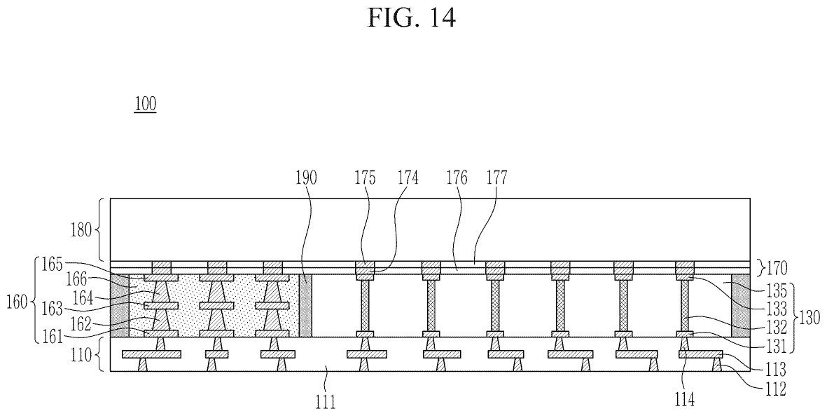

FIG. 14 illustrates a cross-sectional view showing a step of bonding the second semiconductor die 180 on an upper surface of the first semiconductor die 130 and an upper surface of the substrate 160 by performing hybrid bonding as one of the steps of the method of manufacturing the 3D integrated circuit (3DIC) structure 100 according to the embodiment.

Referring to FIG. 14, the hybrid bonding is performed to bond the second semiconductor die 180 to the upper surface of the first semiconductor die 130 and the upper surface of the substrate 160. The first bonding pad 174 on the upper surface of the first semiconductor die 130 and the second bonding pad 175 on the lower surface of the second semiconductor die 180, and the first bonding pad 174 on the upper surface of the substrate 160 and the second bonding pad 175 on the lower surface of the second semiconductor die 180 may be directly bonded by metal-metal hybrid bonding. Metal bonding is performed at interfaces between the first bonding pad 174 on the upper surface of the first semiconductor die 130 and the second bonding pad 175 on the lower surface of the second semiconductor die 180 and between the first bonding pad 174 on the upper surface of the substrate 160 and the second bonding pad 175 on the lower surface of the second semiconductor die 180 by metal-metal hybrid bonding. In an embodiment, the first bonding pad 174 and the second bonding pad 175 may each include copper. In another embodiment, the first bonding pad 174 and the second bonding pad 175 may be a metallic material to which hybrid bonding is applied.

Since the first bonding pad 174 and the second bonding pad 175 are made of a same material, an interface between the first bonding pad 174 and the second bonding pad 175 may disappear after hybrid bonding. The second semiconductor die 180 may be electrically connected to the first semiconductor die 130 through the first bonding pad 174 on the upper surface of the first semiconductor die 130 and the second bonding pad 175 on the lower surface of the second semiconductor die 180. In addition, the second semiconductor die 180 may be electrically connected to the substrate 160 through the first bonding pad 174 on the upper surface of the substrate 160 and the second bonding pad 175 on the lower surface of the second semiconductor die 180.

The first silicon insulating layer 176 on the upper surface of the first semiconductor die 130 and a second silicon insulating layer 177 on the lower surface of the second semiconductor die 180, and the first silicon insulating layer 176 on the upper surface of the substrate 160 and the second silicon insulating layer 177 on the lower surface of the second semiconductor die 180 may be directly bonded by non-metal-non-metal hybrid bonding. A covalent bond is performed at interfaces between the first silicon insulating layer 176 on the upper surface of the first semiconductor die 130 and the second silicon insulating layer 177 on the lower surface of the second semiconductor die 180 and between the first silicon insulating layer 176 on the upper surface of the substrate 160 and the second silicon insulating layer 177 on the lower surface of the second semiconductor die 180 by non-metal-non-metal hybrid bonding.

In an embodiment, the first silicon insulating layer 176 and the second silicon insulating layer 177 may include a silicon oxide or a TEOS forming oxide. In an embodiment, the first silicon insulating layer 176 and the second silicon insulating layer 177 may each include SiO₂. In another embodiment, the first silicon insulating layer 176 and the second silicon insulating layer 177 may each be a silicon nitride, a silicon oxynitride, or other suitable dielectric material. In another embodiment, the first silicon insulating layer 176 and the second silicon insulating layer 177 may each include SiN or SiCN.

The first silicon insulating layer 176 and the second silicon insulating layer 177 may be made of a same material, and after hybrid bonding, an interface between the first silicon insulating layer 176 and the second silicon insulating layer 177 may disappear.

Thereafter, as illustrated in FIG. 1, the external connection structure 120 is formed on the lower surface of the redistribution (RDL) structure.

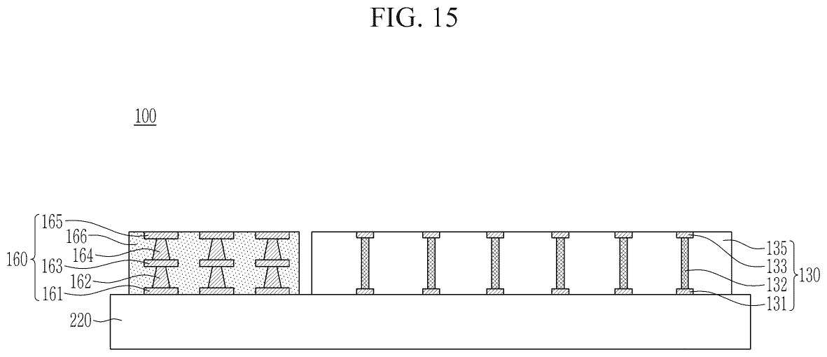

FIG. 15 illustrates a cross-sectional view showing a step of mounting the first semiconductor die 130 and the substrate 160 on a second carrier 220 as one of steps of a method of manufacturing the 3D integrated circuit (3DIC) structure 100 according to another embodiment.

Referring to FIG. 15, the second carrier 220 is provided. The first semiconductor die 130 and the substrate 160 are mounted on the second carrier 220. The first semiconductor die 130 and the substrate 160 are horizontally arranged adjacent to each other and at a same level in a vertical direction. For example, the substrate 160 may be arranged side-by-side to be laterally connected to the side surface of the lower first semiconductor die 130 with the molding material 190. The first semiconductor die 130 is positioned with an active surface facing the second carrier 220. In an embodiment, the first semiconductor die 130 and the substrate 160 may be attached on the second carrier 220 by a laser. In an embodiment, an upper surface of the first semiconductor die 130 may be coplanar with an upper surface of the substrate 160. In an embodiment, a lower surface of the first semiconductor die 130 may be coplanar with a lower surface of the substrate 160. For a material of the second carrier 220, contents of the material of the first carrier 210 illustrated and described in FIG. 9 may be equally applied.

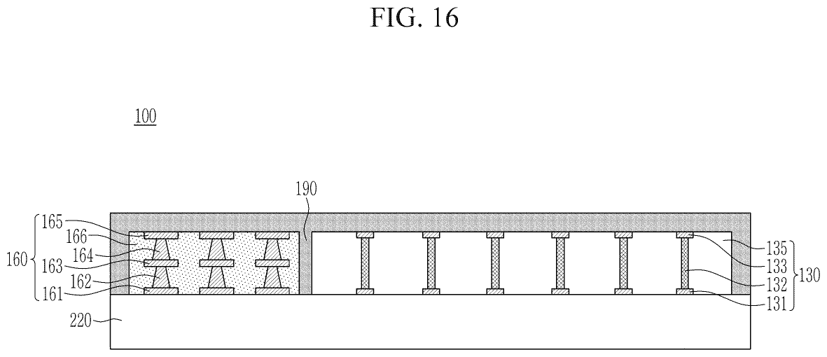

FIG. 16 illustrates a cross-sectional view showing a step of molding the first semiconductor die 130 and the substrate 160 on a second carrier 220 as one of the steps of the method of manufacturing the 3D integrated circuit (3DIC) structure 100 according to the embodiment.

Referring to FIG. 16, the first semiconductor die 130 and the substrate 160 are molded with the molding material 190 on the second carrier 220. For a formation process and material of the molding material 190, contents of the formation process and material of the molding material 190 illustrated and described in FIG. 10 may be applied.

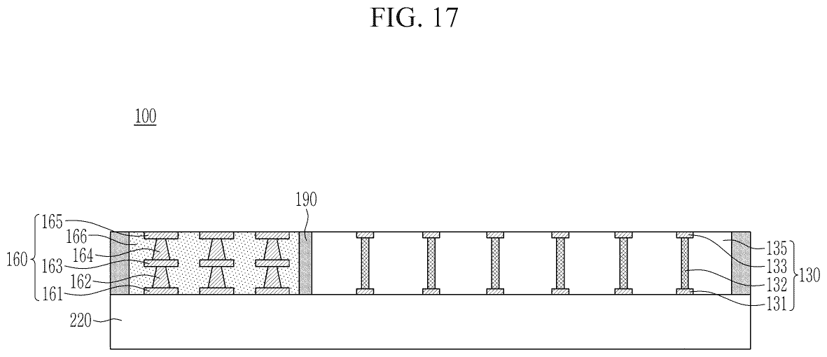

FIG. 17 illustrates a cross-sectional view showing a step of flattening the molding material 190 as one of the steps of the method of manufacturing the 3D integrated circuit (3DIC) structure 100 according to the embodiment.

Referring to FIG. 17, chemical mechanical polishing (CMP) is performed to level an upper surface of the molding material 190. The upper surface of the molding material 190 is planarized by applying a CMP process. After performing the CMP process, the first connection pads 133 are exposed on an upper surface of the first semiconductor die 130 and the third wiring layer 165 is exposed on an upper surface of the substrate 160.

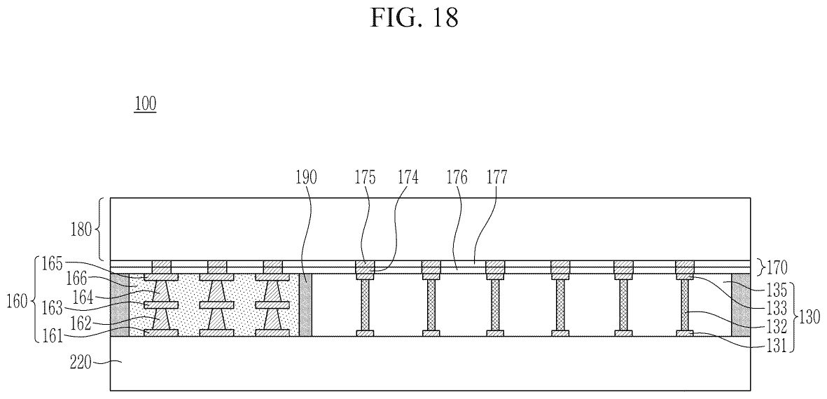

FIG. 18 illustrates a cross-sectional view showing a step of bonding the second semiconductor die 180 on an upper surface of the first semiconductor die 130 and an upper surface of the substrate 160 by performing hybrid bonding as one of the steps of the method of manufacturing the 3D integrated circuit (3DIC) structure 100 according to the embodiment.

Referring to FIG. 18, the hybrid bonding is performed to bond the second semiconductor die 180 to the upper surface of the first semiconductor die 130 and the upper surface of the substrate 160. For a formation process, material and characteristic of the hybrid bonding, contents of the formation process, material and characteristic of the hybrid bonding illustrated and described in FIG. 14 may be equally applied.

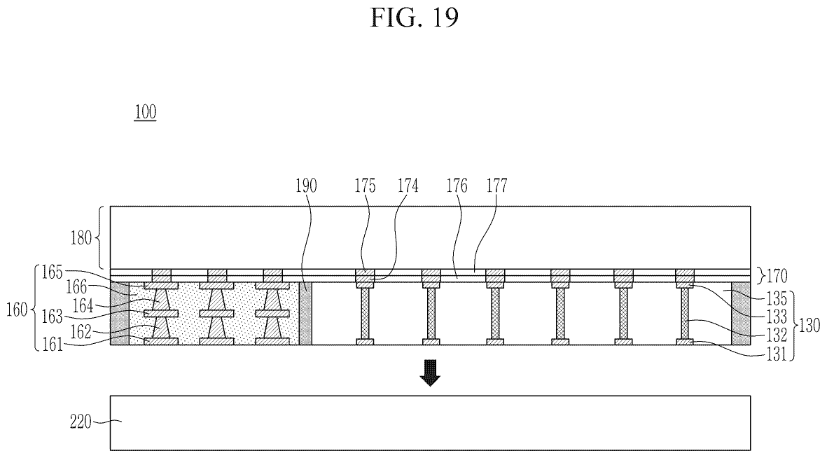

FIG. 19 illustrates a cross-sectional view showing a step of debonding the second carrier 220 from a lower surface of the first semiconductor die 130 and a lower surface of the substrate 160 as one of the steps of the method of manufacturing the 3D integrated circuit (3DIC) structure 100 according to the embodiment.

Referring to FIG. 19, the second carrier 220 is debonded from the lower surface of the first semiconductor die 130 and the lower surface of the substrate 160.

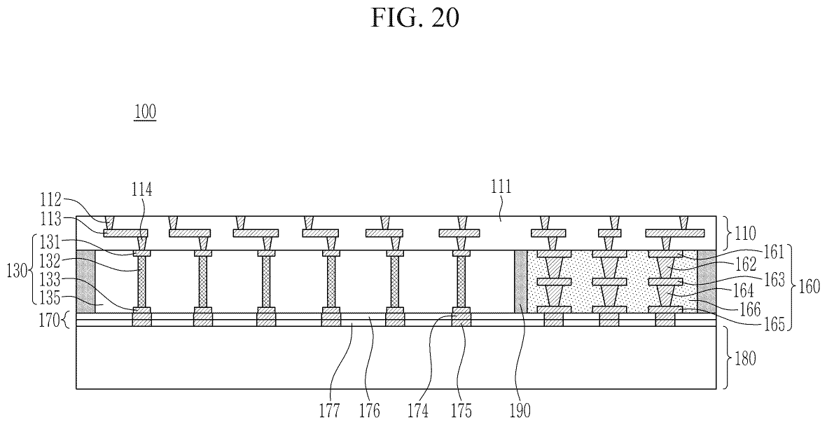

FIG. 20 illustrates a cross-sectional view showing a step of forming the redistribution (RDL) structure 100 on a lower surface of the first semiconductor die 130 and a lower surface of the substrate 160 as one of the steps of the method of manufacturing the 3D integrated circuit (3DIC) structure 100 according to the embodiment.

For a formation process, material and characteristic of the redistribution (RDL) structure 110 in FIG. 20, contents of the formation process, material and characteristic of the redistribution (RDL) structure 110 illustrated and described in FIG. 12 may be equally applied.

Thereafter, as illustrated in FIG. 1, the external connection structure 120 is formed on the lower surface of the redistribution (RDL) structure.

While embodiments have been described with reference to the figures, it will be understood by those of ordinary skill in the art that various changes in form and details may be made therein without departing from the spirit and scope as defined by the following claims and their equivalents.

What is claimed is:

1. A three-dimensional (3D) integrated circuit structure comprising:
a redistribution structure;
a first semiconductor die on the redistribution structure;
a substrate on the redistribution structure and adjacent to the first semiconductor die;
a molding material on the redistribution structure and between the first semiconductor die and the substrate;
an interconnection structure on the substrate and the first semiconductor die, the interconnection structure comprising a plurality of first bonding pads and a plurality of second bonding pads, and each second bonding pad of the plurality of second bonding pads being directly bonded to each first bonding pad of the plurality of first bonding pads; and
a second semiconductor die on the interconnection structure.

2. The 3D integrated circuit structure of claim 1, wherein a footprint of the first semiconductor die and a footprint of the substrate are included within a footprint of the second semiconductor die.

3. The 3D integrated circuit structure of claim 1, wherein the substrate is adjacent to a first side surface of the first semiconductor die.

4. The 3D integrated circuit structure of claim 3, further comprising at least one additional substrate on the redistribution structure and adjacent to the first semiconductor die, the at least one additional substrate being molded by the molding material.

5. The 3D integrated circuit structure of claim 4, wherein one substrate of the at least one additional substrate is adjacent to a second side surface of the first semiconductor die opposite to the first side surface.

6. The 3D integrated circuit structure of claim 1, wherein the substrate is adjacent to at least one side surface of the first semiconductor die.

7. The 3D integrated circuit structure of claim 1, wherein the substrate comprises an embedded trace substrate (ETS).

8. The 3D integrated circuit structure of claim 1, wherein the 3D integrated circuit structure is a system on chip (SOC).

9. The 3D integrated circuit structure of claim 1, wherein the first semiconductor die comprises at least one of a central processing unit (CPU) and a graphics processing unit (GPU), and
wherein the second semiconductor die comprises at least one of a sensor or a communication chip.

10. A three-dimensional (3D) integrated circuit structure comprising:
a redistribution structure comprising a plurality of redistribution vias;
a first semiconductor die on the redistribution structure;
a substrate on the redistribution structure and adjacent to the first semiconductor die;
a molding material on the redistribution structure and molding the first semiconductor die and the substrate;
an interconnection structure on the substrate and the first semiconductor die, the interconnection structure comprising:
a plurality of first bonding pads;
a plurality of second bonding pads;
a first silicon insulating layer adjacent to side surfaces of the plurality of first bonding pads; and
a second silicon insulating layer adjacent to side surfaces of the plurality of second bonding pads, each second bonding pad of the plurality of second bonding pads being directly bonded to each first bonding pad of the plurality of first bonding pads; and
a second semiconductor die on the interconnection structure.

11. The 3D integrated circuit structure of claim 10, wherein the first semiconductor die comprises:
a plurality of first connection pads;
a plurality of second connection pads; and
a plurality of through silicon vias,
wherein a first end of each through silicon via among the through silicon vias contacts each first connection pad among the plurality of first connection pads, and
wherein a second end of each through silicon via contacts each second connection pad among the second connection pads.

12. The 3D integrated circuit structure of claim 11, wherein each of the plurality of first connection pads is directly bonded to each of a portion of redistribution vias among the redistribution vias.

13. The 3D integrated circuit structure of claim 11, wherein each of the second connection pads is directly bonded to each of a portion of first bonding pads among the plurality of first bonding pads.

14. The 3D integrated circuit structure of claim 10, wherein the substrate comprises a plurality of wiring layers, and
wherein each wiring layer at a lowermost level among the wiring layers is directly bonded to each of a portion of redistribution vias among the redistribution vias.

15. The 3D integrated circuit structure of claim 10, wherein a width of an uppermost portion in each redistribution via among the redistribution vias is smaller than a width of a lowermost portion in each redistribution via among the redistribution vias.

16. The 3D integrated circuit structure of claim 10, wherein the second silicon insulating layer is directly bonded to the first silicon insulating layer.

17. The 3D integrated circuit structure of claim 10, wherein an upper surface of the first semiconductor die is coplanar with an upper surface of the substrate.

18. A manufacturing method of a three-dimensional (3D) integrated circuit structure, comprising:
providing a lower surface of a first semiconductor die and a lower surface of a substrate on a carrier;
molding the first semiconductor die and the substrate on the carrier with a molding material;
performing hybrid bonding to electrically connect the lower surface of the second semiconductor die to an upper surface of the first semiconductor die and an upper surface of the substrate;
separating the carrier from the lower surface of the first semiconductor die and the lower surface of the substrate; and
forming a redistribution structure on the lower surface of the first semiconductor die and the lower surface of the substrate.

19. The manufacturing method of claim 18, further comprising performing a chemical mechanical polishing (CMP) process on the molding material after the molding of the first semiconductor die and the substrate on the carrier with the molding material.

20. The manufacturing method of claim 18, further comprising providing an external connection structure on the lower surface of the redistribution structure after the forming of the redistribution structure on the lower surface of the first semiconductor die and the lower surface of the substrate.
